(19) United States
(12) Patent Application Publication
(10) Pub. No.: US 2015/0200176 A1
(43) Pub. Date: Jul. 16, 2015

(54) SEMICONDUCTOR DEVICE AND METHOD FOR PRODUCING SAME

(71) Applicant: SHARP KABUSHIKI KAISHA, Osaka-shi, Osaka (JP)

(72) Inventors: Katsunori Mori, Osaka-shi (JP); Yasuki Fukui, Osaka-shi (JP); Kazuaki Tatsumi, Osaka-shi (JP); Takayuki Mihara, Osaka-shi (JP)

(21) Appl. No.: 14/420,049

(22) PCT Filed: Aug. 2, 2013
(86) PCT No.: PCT/JP2013/071005

§ 371 Date: Feb. 6, 2015

(30) Foreign Application Priority Data
Aug. 8, 2012 (JP) 2012-176417

(51) Int. Cl. H01L 23/00; H01L 25/065; H01L 25/00

(52) U.S. Cl. CPC H01L 24/17; H01L 25/50; H01L 25/0657; H01L 24/11; H01L 24/81; H01L 2225/06513; H01L 2225/06517; H01L 2225/0652; H01L 2224/1134; H01L 2224/1146; H01L 2224/812; H01L 2224/81801; H01L 2224/13147; H01L 2224/13144; H01L 2224/16113; H01L 2224/16148; H01L 2224/16238; H01L 2224/16258

(57) ABSTRACT

A mounting structure of a semiconductor device is configured by connecting (i) a first protruding electrode [a bump (A5)] formed on a first electronic component [a substrate (2) or a semiconductor element (A1)] and (ii) a second protruding electrode [a bump (B6)] formed on a second electronic component [a semiconductor element (B11)]. The first protruding electrode and the second protruding electrodes are made of different metal materials. The first protruding electrode is harder than the second protruding electrode, has a pointed end, and is embedded in the second protruding electrode.

### TECHNICAL FIELD

The present invention relates to a semiconductor device manufactured by using a flip chip technique and a method for manufacturing a semiconductor device by using the flip chip technique.

### BACKGROUND ART

With the recent miniaturization of electronic apparatuses, semiconductor devices also have increased their respective signaling and operation processing speeds and have obtained multiple functions. With an increase in the number of signal terminals and an increase in the number of signal lines as well as an increase in capacity of storage devices, there are growing demands for further high-density integration and further high-density mounting.

A mounting method such as a stack method or a flip chip method has been used for packaging semiconductor elements. Notably, the flip chip method is a method which makes it possible to achieve highest-density and shortest connections.

In the flip chip method, a bump or a post is formed on each electrode pad of a semiconductor element or on each substrate terminal of a mounting substrate, and with the bumps or the posts facing each other, the bumps or the posts are mounted on and electrically bonded to each other. Known examples of bonding methods based on the flip chip method include a method in which the bumps or the posts are bonded to each other by soldering or via an anisotropic conductive sheet, a method in which the bumps or the posts are made of the same type of metal and are bonded by ultrasonic thermal pressure bonding, and the like. Patent Literatures 1 through discloses the examples of bonding based on the conventional methods.

### CITATION LIST

### Patent Literatures

Patent Literature 1

U.S. Pat. No. 6,229,220 (Issue Date: May 8, 2001)

Patent Literature 2

Japanese Patent Application Publication, Tokukai, No. 2001-60602 A (Publication Date: Mar. 6, 2001)

Patent Literature 3

Japanese Patent Application Publication, Tokukai, No. 2003-45911 A (Publication Date: Feb. 14, 2003)

### SUMMARY OF INVENTION

### Technical Problem

However, in such electrical bonding as that mentioned above, there remains a problem with the method in which the bumps or the posts are bonded to each other by soldering or via an anisotropic conductive sheet and a problem with the method in which the bumps or the posts are made of the same type of metal and are bonded by ultrasonic thermal pressure bonding.

Specifically, in a case where solder is used for bonding the bumps or the posts to each other, a large number of processes and materials, such as the application of solder to the bumps and the posts, the application of flux, reflow, and the removal of flux, are required. This means long time and high cost. Moreover, electrical conduction is impossible due to (i) a short circuit with an adjacent terminal by a fine-pitch solder bridge or (ii) the remelting of a solder joint by heat of reflow, for example, which is applied through the assembly by a user.

In a case where the bumps or the posts are bonded to each other via an anisotropic conductive sheet, the reliability of connection can decrease due to thermal stress.

In a case where the bumps or the posts made of the same type of metal are bonded to each other, it is difficult for newly-formed surfaces to be exposed at the interface between the metals only with heat and load and it is therefore difficult for the bumps or the posts to be bonded to each other. As a measure to bond the bumps or the posts made of the same type of metal to each other, the use of ultrasonic waves makes it possible to easily expose newly-formed surfaces and to bond the bumps or the posts to each other even when they are made of the same type of metal. However, a possibility still remains that the amplitude of ultrasonic waves may cause damage such as deformation or detachment.

The present invention has been made to solve the problems mentioned above. An object of the present invention is to provide a semiconductor device that enables electrical bonding with high reliability and a method for manufacturing such a semiconductor device.

### Solution to Problem

In order to solve the problems mentioned above, a semiconductor device according to the present invention includes: a first electronic component having a first protruding electrode; and a second electronic component having a second protruding electrode, the second protruding electrode being connected to the first protruding electrode, the first protruding electrode and the second protruding electrode being made of different metal materials, the first protruding electrode being harder than the second protruding electrode, the first protruding electrode having an end facing the second protruding electrode and embedded in the second protruding electrode.

### Advantageous Effects of Invention

The present invention brings about an advantageous effect of making it possible to perform flip chip bonding that enables highly-reliable electrical bonding.

### BRIEF DESCRIPTION OF DRAWINGS

FIG. 1 is a set of cross-sectional views (a), (b), (c), and (d) each showing a mounting structure of a semiconductor device according to the present invention.

FIG. 2A is a cross-sectional view of bonding between connection terminals according to the present invention.

FIG. 2B is a cross-sectional view of bonding between connection terminals according to the present invention.

FIG. 2C is a cross-sectional view of bonding between connection terminals according to the present invention.

FIG. 2D is a cross-sectional view of bonding between connection terminals according to the present invention.

FIG. 2E is a cross-sectional view of bonding between connection terminals according to the present invention.

FIG. 2F is a cross-sectional view of bonding between connection terminals according to the present invention.

FIG. 2G is a cross-sectional view of bonding between connection terminals according to the present invention.

FIG. 3 is a set of cross-sectional views (a), (b), and (c) each showing a modification of a mounting structure of a semiconductor device according to the present invention.

FIG. 4A is a cross-sectional view of an embodiment of bonding between conventional connection terminals.

FIG. 4B is a cross-sectional view of an embodiment of bonding between conventional connection terminals.

FIG. 4C is a cross-sectional view of an embodiment of bonding between conventional connection terminals.

FIG. 4D is a cross-sectional view of an embodiment of bonding between conventional connection terminals.

FIG. 5 is a diagram showing an embodiment of a method for forming a bump by using a wire bonding device.

FIG. 6 is a diagram showing an embodiment of a method for forming a bump by using a plating method.

FIG. 7 is a flow chart showing a process for manufacturing of a semiconductor device according to the present invention.

### DESCRIPTION OF EMBODIMENTS

Embodiments of a semiconductor device according to the present invention are described below.

### Embodiment 1 of Mounting Structure of Semiconductor Device

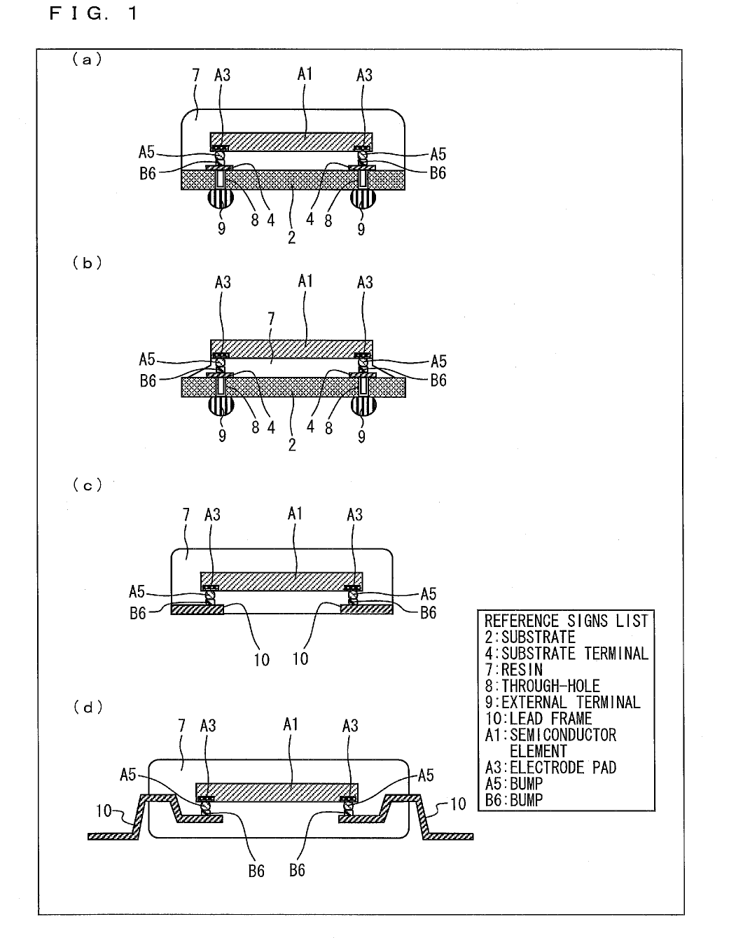

A mounting structure of a semiconductor device according to an embodiment of the present invention is described below with reference to (a) of FIG. 1.

(a) of FIG. 1 is a cross-sectional view of a mounting structure of a semiconductor device according to the present invention.

As shown in (a) of FIG. 1, the semiconductor device includes two components (a semiconductor element A1 and a substrate 2). Each of the components has at least one connection terminal (an electrode pad A3 and a substrate terminal 4) on a surface thereof. The components (the semiconductor element A1 and the substrate 2) are electrically bonded to each other via a plurality of connection terminals (electrode pads A3 and substrate terminals 4) of each of the components. The electrical bonding is made with a bump A5 and a bump B6 that are made of different metals. A resin 7 is provided so as to cover a front surface of the substrate 2. An external terminal 9 is provided on a rear surface of the substrate 2 so as to be electrically connected to the electrical bonding via the substrate terminal 4 and a through-hole 8.

A feature of (a) of FIG. 1 is that the electrical bonding is direct bonding between the bump A5 of each of the electrode pads A3 and the bump B6 of each of the substrate terminals 4 and the bump A5 and the bump B6 are made of different metals differing in hardness.

When metals differing in hardness are used as a junction of the electrical bonding, the harder bump is pressed and bonded to the softer metal bump, as if digging, through the application of a load during bonding. The interface between the bonded surfaces as viewed in cross section is not even, and the bonded surfaces are shaped into a projection and a depression, respectively. A relationship between the projection and the depression causes friction to be created due to a slide at the interface between the different metal bumps and makes it easier for newly-formed surfaces to be exposed, so that the metal bumps are directly bonded to each other. This makes it possible to expose newly-formed surfaces without using ultrasonic waves. Therefore, the problem with ultrasonic bonding can be avoided. Specifically, damage such as deformation or detachment of a bump due to the amplitude of ultrasonic waves can be avoided.

Since solder bonding is no longer required, either, the problem with solder bonding can be avoided, too. Specifically, a large number of processes and materials, cost and time that are required by solder bonding, such as the application of solder, the application of flux, reflow, and the removal of flux, can be reduced. Moreover, the failure of electrical conduction due to (i) a short circuit with an adjacent terminal by a fine-pitch solder bridge or (ii) the remelting of a solder joint by heat of reflow, for example, which is applied through the assembly by a user can be avoided, too.

### Embodiment 2 of Mounting Structure of Semiconductor Device

Another mounting structure of a semiconductor device according to an embodiment of the present invention is described below with reference to (b) of FIG. 1.

(b) of FIG. 1 is a cross-sectional view of a mounting structure of a semiconductor device according to the present invention.

As shown in (b) of FIG. 1, the semiconductor device includes two components (a semiconductor element A1 and a substrate 2). Each of the components has at least one connection terminal (an electrode pad A3 and a substrate terminal 4) on a surface thereof. The components (the semiconductor element A1 and the substrate 2) are electrically bonded to each other via a plurality of connection terminals (electrode pads A3 and substrate terminals 4) of each of the components. The electrical bonding is made with a bump A5 and a bump B6 that are made of different metals differing in hardness. A resin 7 is provided so as to fill a space between the semiconductor element A1 and the substrate 2. An external terminal 9 is provided on a rear surface of the substrate 2 so as to be electrically connected to the electrical bonding via the substrate terminal 4 and a through-hole 8.

A difference of (b) of FIG. 1 from (a) of FIG. 1 is that the resin coating is provided only between the semiconductor and the substrate. The provision of the resin to protect the semiconductor element, for example, only at the junction reduces the amount of resin that is consumed, thus making it possible to reduce the cost of manufacturing the semiconductor device.

### Embodiment 3 of Mounting Structure of Semiconductor Device

Another mounting structure of a semiconductor device according to an embodiment of the present invention is described below with reference to (c) of FIG. 1.

(c) of FIG. 1 is a cross-sectional view of a mounting structure of a semiconductor device according to the present invention.

As shown in (c) of FIG. 1, the semiconductor device includes two components (a semiconductor element A1 and a lead frame 10). Each of the components has at least one connection terminal (an electrode pad A3 and the lead frame (lead) 10) on a surface thereof. The components (the semiconductor element A1 and the lead frame 10) are electrically bonded to each other via a plurality of connection terminals (an electrode pad A3 and the lead frame (lead) 10) of each of the components. The electrical bonding is made with a bump A5 and a bump B6 that are made of different metals differing in hardness. A resin 7 is provided so as to cover a front surface of the lead frame 10.

A difference of (c) of FIG. 1 from (a) of FIG. 1 is found in components. The use of the lead frame 10 instead of the substrate 2 according to Embodiment 1 allows the lead frame 10 to function as an external terminal. This eliminates the need for (i) the through-hole 8, which is needed to connect the external terminal 9 to the substrate 2 and which is bored through the substrate 2 and (ii) the external terminal 9 (see (a) in FIG. 1). This leads to a reduction in the number of steps of a process for manufacturing the semiconductor device, and by extension to a reduction in the cost of manufacturing the semiconductor device.

### Embodiment 4 of Mounting Structure of Semiconductor Device

Another mounting structure of a semiconductor device according to an embodiment of the present invention is described below with reference to (d) of FIG. 1.

(d) of FIG. 1 is a cross-sectional view of a mounting structure of a semiconductor device according to the present invention.

A difference of (d) of FIG. 1 from (c) of FIG. 1 is found in the shape of a lead frame. Since the lead frame can take any shape, the lead frame can be disposed at any location where it is needed.

Furthermore, embodiments of bonding between one connection terminal and another according to the present invention are described below.

### Embodiment 1 of Bonding between Connection Terminals

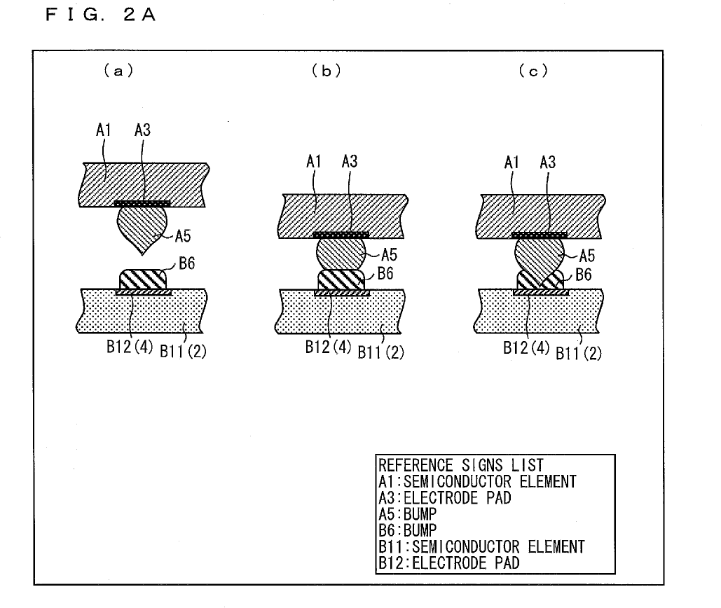

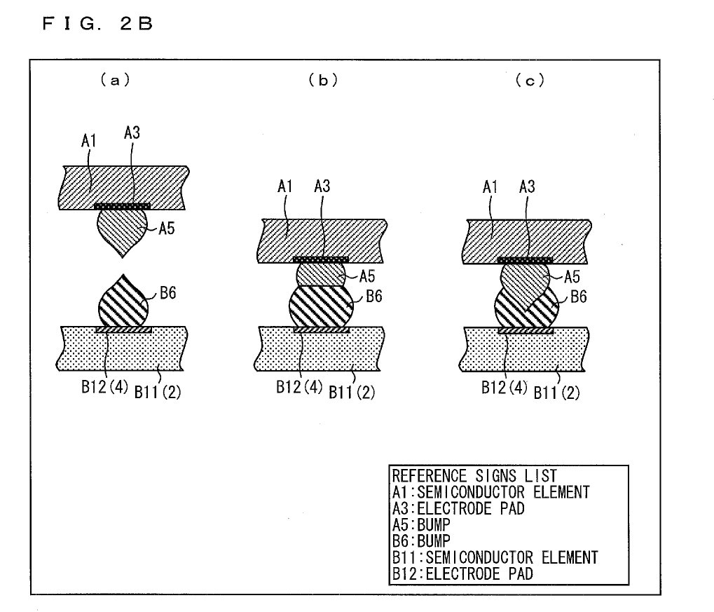

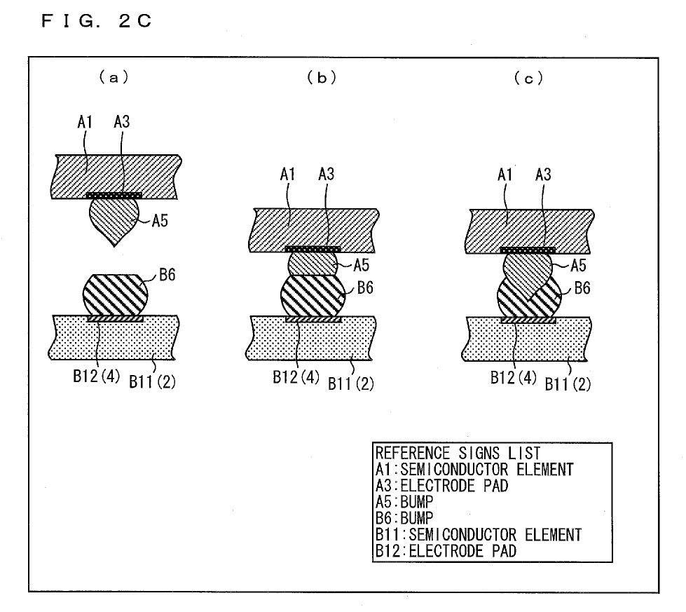

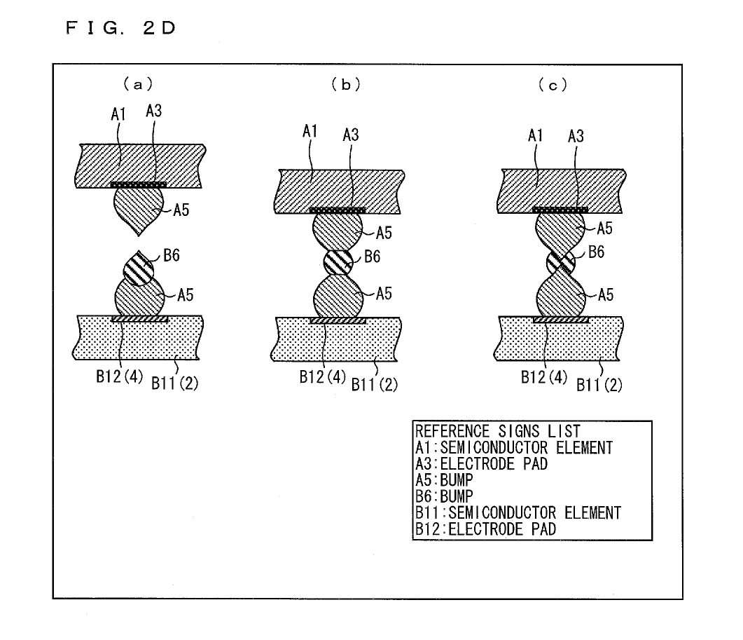

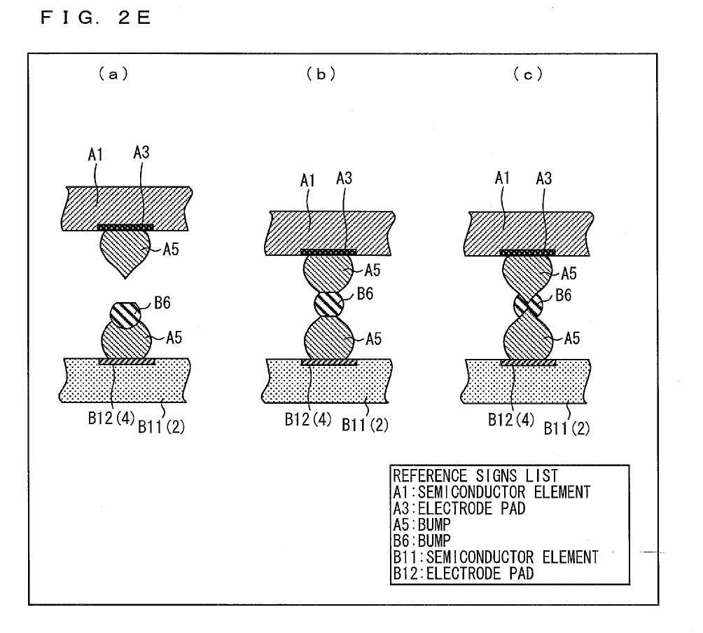

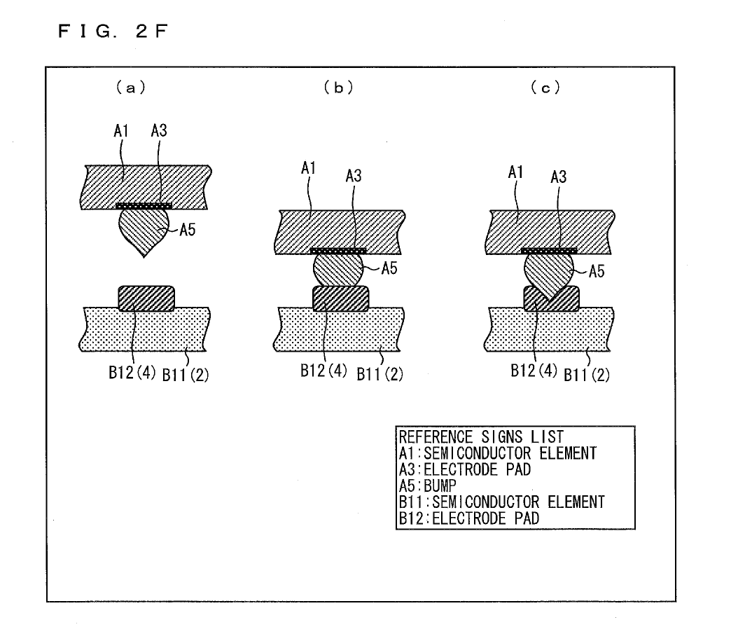

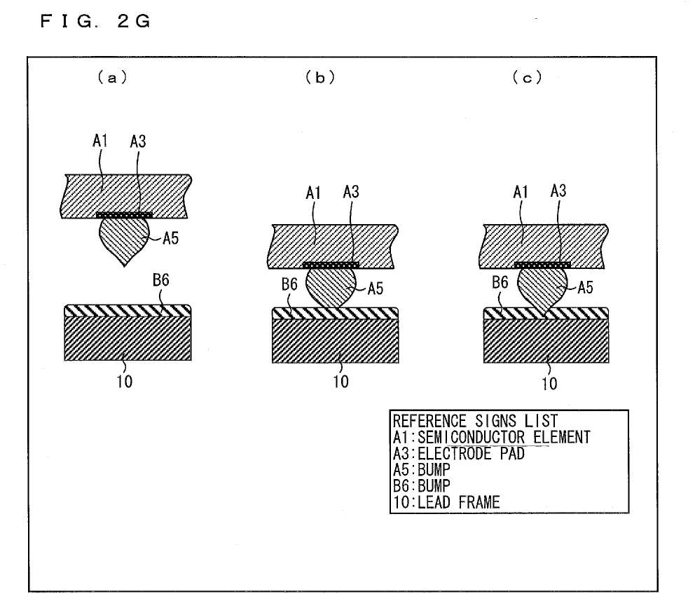

Bonding between connection terminals according to an embodiment of the present invention is described below with reference to FIG. 2A.

FIG. 2A is a cross-sectional view of bonding between connection terminals according to the present invention.

FIG. 2A is an example of bonding between a semiconductor element A1 and a semiconductor element B11 (or a substrate 2). A hard metal bump A5 on an electrode pad A3 of the semiconductor element A1 is one formed on a ground wafer by a wire bonding device and a bump bonding device. A soft metal bump B6 is formed on an electrode pad B12 (or a substrate terminal 4) of the semiconductor element B11 (or the substrate 2) by a plating method and an evaporation method. Flip chip bonding between the hard metal bump A5 and the soft metal bump B6 is performed with the hard metal bump A5 and the soft metal bump B6 facing each other. As a result, the bump A5 is shaped into a projection while the bump B6 is shaped into a depression (see the cross-section shown in (c) of FIG. 2A).

Here, the bump formation is described by taking, as examples, a method for forming a bump by using a wire bonding device and a method for forming a bump using a plating method.

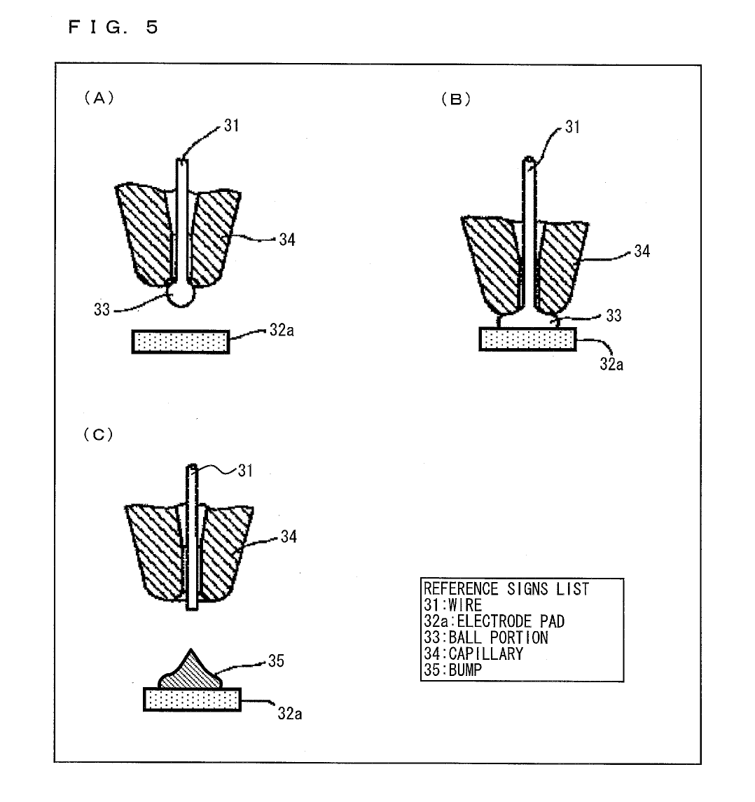

First, an example of the method for forming a bump by using a wire bonding device is described with reference to FIG. 5. The method for forming a bump by using a wire bonding device is performed by using a capillary 34 (through which a wire 31 is inserted) of the wire bonding device. First, a ball portion 33 is formed, for example, by spark discharge on the wire 31 sticking out from a tip of the capillary 34 (see (A) of FIG. 5). Next, the ball portion 33 thus formed is pressed onto an electrode pad 32a by using the capillary 34, and then is bonded to the electrode pad 32a, for example, by an ultrasonic welding method (see (B) of FIG. 5). Then, the bump 35 is formed by cutting the wire near the root of the ball thus bonded (see (C) of FIG. 5).

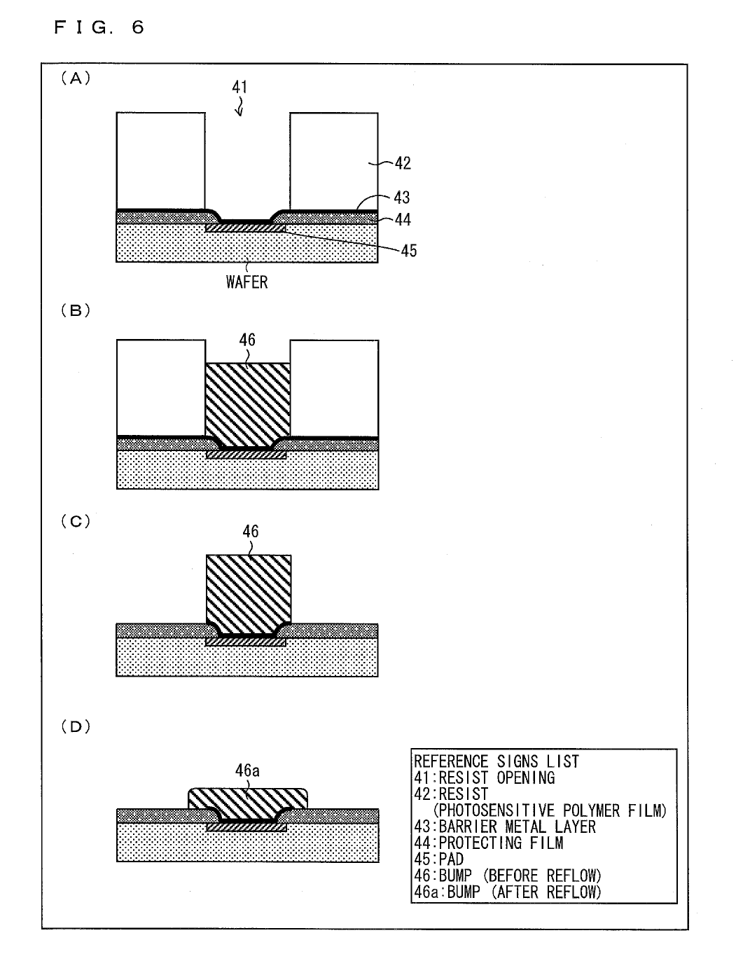

Next, an example of the method for forming a bump by using a plating method is described with reference to FIG. 6.

A resist opening 41 is formed on a wafer for a bump to be formed by plating (see (A) of FIG. 6). The resist opening 41 is formed by opening a resist 42 above a wiring terminal portion connected to a circuit within the chip. This wiring terminal portion is called a pad 45. Formed below the resist 42 is a barrier metal layer 43 (which is a metal film for preventing the diffusion of bump metal and which has conductivity). Formed below the barrier metal layer 43 is a protecting film 44. Electroplating based on electrolysis is performed by passing a current through the barrier metal layer 43 from an edge of the wafer (see (B) of FIG. 6). Since only the resist opening 41 is in contact with a plating liquid, a bump 46 is formed along the resist opening 41. After the bump 46 is formed by plating, the wafer is transferred to a device for the next step, and is then subjected to resist removing and barrier metal etching (an unnecessary portion of the barrier metal layer which is located at a place other than the bump is removed by etching) (see (C) of FIG. 6). After that, by heating the wafer in a reflow furnace, a bump 46a is formed out of the bump 46 (see (D) of FIG. 6).

A stud bump can be formed by forming a bump by using a wire bonding device. A plated bump can be formed by forming a bump by using a plating method.

In addition to the problems mentioned above, a reduction in the cost of manufacturing the semiconductor device is also required. Possible reasons for the increase in the manufacturing cost are as follows:

(1) In a case where the bump forming line and the manufacturing line for flip chip bonding are different from each other and transportation between the lines is required, (i) the junction between the bump thus formed and the electrode pad and (ii) the junction between the bump thus formed and the substrate terminal may be damaged during transportation to cause cost increases.

(2) Since, in a case where the bump formation is outsourced, bumps are formed on all semiconductor elements within a wafer, the addition of the cost of the bumps formed on defective semiconductor elements to the cost of the bumps formed on non-defective semiconductor elements causes cost increases.

(3) In a case where, regarding the positions where bumps are formed, the bumps are formed on a wafer instead of being formed individually, shifts in position of all of the bumps within the wafer due to an abnormality in manufacturing causes cost increases.

(4) If, in a case where the bump formation is outsourced, any bumps are unformed or dropped, the introduction of an inspection for detecting such bumps causes cost increases.

The selection of a method for forming a bump in the manufacture of a semiconductor device is a key to reducing cost increases at any of such manufacturing stages.

By forming either of the bumps on a wafer with a wire bonding device and a bump bonding device, the positions where the bumps are formed can be adjusted individually with respect to the electrode pads, the substrate terminals, and the like (see FIG. 2A). Therefore, the bumps can be formed with high positional accuracy, and unformed or unattached bumps can be detected. Moreover, the same effects can be brought about even in a case where bumps are formed on each individual semiconductor chip into which a wafer has been divided. Furthermore, the formation of bumps on a ground wafer brings about the following merits. First, since the positions of the semiconductor elements are fixed, it takes a shorter time to detect the positions and it is easy to adjust the positions. Second, since the semiconductor devices are not individually transported, it takes a shorter time to form the bumps. Third, although grinding imposes constraints on the conditions under which the bumps are formed, no further damage is done to the bumps after grinding, provided bonding is possible.

Conversely, in a case where bumps are formed on an unground wafer, there is no need for a sheet on which a thinly-ground wafer is supported. This makes it possible to form the bumps at high temperature. However, grinding after bump formation presents such problems as causing bubbles to be formed inside when a protecting sheet is attached onto the surface on which the bumps have been formed and causing the bumps to drop when the sheet is removed.

Moreover, the formation of bumps by using a wire bonding device and a bump bonding device allows each of the bump to have a pointed end. The pointed end of the bump makes easier for the bump to be embedded in a matching protruding electrode and therefore possible for the bump to be more firmly bonded to the matching protruding electrode.

As described above, the formation of at least one bump on a ground wafer by using a wire bonding device and a bump bonding device makes it possible to perform flip chip bonding that enables highly-reliable electrical bonding.

Moreover, the use of different metals differing in hardness at the junction enables direct bonding, and brings about the effects of [Embodiment 1 of Mounting Structure of Semiconductor Device].

### Embodiment 2 of Bonding between Connection Terminals

Bonding between connection terminals according to an embodiment of the present invention is described with reference to FIG. 2B.

FIG. 2B is a cross-sectional view of bonding between connection terminals according to the present invention.

FIG. 2B is an example of bonding between a semiconductor element A1 and a semiconductor element B11 (or a substrate 2). A hard metal bump A5 is formed on an electrode pad A3 of the semiconductor element A1 by using a wire bonding device and a bump bonding device. A soft metal bump B6 is formed on an electrode pad B12 (or a substrate terminal 4) of the semiconductor element B11 (or the substrate 2) by using a wire bonding device and a bump bonding device. Flip chip bonding between the hard metal bump A5 and the soft metal bump B6 is performed with the hard metal bump A5 and the soft metal bump B6 facing each other. As a result, the bump A5 is shaped into a projection while the bump B6 is shaped into a depression (see the cross-section shown in (c) of FIG. 2B).

A difference from FIG. 2A is that all bumps are formed by using a wire bonding device and a bump bonding device. The formation of bumps by a plating method and an evaporation method presents the following problems (cost increases):

(1) In a case where the bump forming line and the manufacturing line for flip chip bonding are different from each other, (i) the junction between the bump thus formed and the electrode pad and (ii) the junction between the bump thus formed and the substrate terminal may be damaged during transportation to cause cost increases.

(2) Since, in a case where the bump formation is outsourced, bumps are formed on all semiconductor elements within a wafer, the addition of the cost of the bumps formed on defective semiconductor elements to the cost of the bumps formed on non-defective semiconductor elements causes cost increases.

(3) In a case where, regarding the positions where bumps are formed, the bumps are formed on a wafer instead of being formed individually, shifts in position of all of the bumps within the wafer due to an abnormality in manufacturing causes cost increases.

(4) If any bumps are unformed or dropped, the introduction of an inspection for detecting such bumps causes cost increases.

These problems (cost increases), which are presented by the formation of bumps by a plating method and an evaporation method, can be avoided by forming the bumps by using a wire boding device and a bump bonding device.

### Embodiment 3 of Bonding between Connection Terminals

Bonding between connection terminals according to an embodiment of the present invention is described below with reference to FIG. 2C.

FIG. 2C is a cross-sectional view of bonding between connection terminals according to the present invention.

FIG. 2C is an example of bonding between a semiconductor element A1 and a semiconductor element B11 (or a substrate 2).

A difference from FIG. 2B is that leveling is performed on a soft bump B6 (see FIG. 2B) to form a planar portion that faces the bump A5. According to the configuration, since the soft metal bump comes to have a wider planar portion when the end of the hard metal bump is pressed onto the soft metal bump, a relationship between a projection and a depression as viewed in cross section can be easily established even in a case where a shift in position occurs during flip chip bonding. This ensures a stable bonding state.

### Embodiment 4 of Bonding between Connection Terminals

Bonding between connection terminals according to an embodiment of the present invention is described below with reference to FIG. 2D.

FIG. 2D is a cross-sectional view of bonding between connection terminals according to the present invention.

FIG. 2D is an example of bonding between a semiconductor element A1 and a semiconductor element B11 (or a substrate 2). A hard metal bump A5 is formed on an electrode pad A3 of the semiconductor element A1 by using a wire bonding device and a bump bonding device. A hard metal bump A5 is formed also on an electrode pad B12 (or a substrate terminal 4) of the semiconductor element B11 (or the substrate 2) by using the wire bonding device and the bump bonding device. A soft metal bump B6 is formed on the bump A5 on the electrode pad B12 (or the substrate terminal 4). Flip chip bonding between the hard metal bump A5 and the soft metal bump B6 is performed with the hard metal bump A5 and the soft metal bump B6 facing each other. As a result, the bump A5 is shaped into a projection while the bump B6 is shaped into a depression (see the cross-section shown in (c) in FIG. 2D).

A difference from FIG. 2A is that the hard metal bumps A5 are formed on (i) the electrode pad A3 of the semiconductor element A1 and (ii) the electrode pad B12 of the semiconductor element B11 (or the substrate terminal 4 of the substrate 2) located opposite to the electrode pad A3 of the semiconductor element A1, respectively, by using a wire bonding device and a bump bonding device. Another difference is that a soft metal bump B6 is formed on the bump A5 on the opposite electrode pad B12 (or the substrate terminal 4 of the substrate 2) and then flip chip bonding is performed. Bonding components to each other by using three bumps makes it possible, for example, to secure a clearance between one component and another, to increase a level of filling, and to adjust the clearance in the case of a problem such as a failure to fill a space between the components with a fixing material or a sealing material.

### Embodiment 5 of Bonding between Connection Terminals

Bonding between connection terminals according to an embodiment of the present invention is described below with reference to FIG. 2E.

FIG. 2E is a cross-sectional view of bonding between connection terminals according to the present invention.

FIG. 2E is an example of bonding between a semiconductor element A1 and a semiconductor element B11 (or a substrate 2). A difference from FIG. 2D is that leveling is performed on a soft bump B6 (see FIG. 2D) to form a planar portion opposite to a bump A5 on an electrode pad A3 of the semiconductor element A1. According to the configuration, since the soft metal bump comes to a wider planar portion when the end of the hard metal bump is pressed onto the soft metal bump, a relationship between a projection and a depression as viewed in cross section can be easily established even in a case where a shift in position occurs during flip chip bonding. This ensures a stable bonding state.

### Embodiment 6 of Bonding between Connection Terminals

Bonding between connection terminals according to an embodiment of the present invention is described below with reference to FIG. 2F.

FIG. 2F is a cross-sectional view of bonding between connection terminals according to the present invention.

FIG. 2F is an example of bonding between a semiconductor element A1 and a semiconductor element B11 (or a substrate 2). A hard metal bump A5 is formed on an electrode pad A3 of the semiconductor element A1 by using a wire bonding device and a bump bonding device. An electrode pad B12 (or a substrate terminal 4) of the semiconductor element B11 (or the substrate 2) has such a thickness as to perform a role equivalent to that of a soft metal bump B6. Flip chip bonding between the hard metal bump A5 and the electrode pad B12 (or the substrate terminal 4) of the semiconductor element B11 (or the substrate 2) is performed with the hard metal bump A5 and the electrode pad B12 (or the substrate terminal 4) of the semiconductor element B11 (or the substrate 2) facing each other. As a result, the bump A5 is shaped into a projection while the electrode pad B12 (or the substrate terminal 4) is shaped into a depression (see the cross-section shown in (c) of FIG. 2F).

A difference from FIG. 2A is that the electrode pad of the opposite semiconductor element or the substrate terminal 4 of the substrate 2 has such a thickness as to perform a role equivalent to that the soft metal bump B6, and (i) the bump and the electrode pad or (ii) the bump and the substrate terminal 4 of the substrate 2 are directly bonded to each other. The configuration makes it possible to omit the step of forming a soft bump B6, thus making it possible to speed up the process.

### Embodiment 7 of Bonding between Connection Terminals

Bonding between connection terminals according to an embodiment of the present invention is described below with reference to FIG. 2G.

FIG. 2G is a cross-sectional view of bonding between connection terminals according to the present invention.

FIG. 2G is an example of bonding between a semiconductor element A1 and a lead frame 10. A hard metal bump A5 is formed on an electrode pad A3 of the semiconductor element A1 by using a wire bonding device and a bump bonding device. A soft metal bump 6 is formed on the lead frame 10 by a plating method and an evaporation method. Flip chip bonding between the hard metal bump A5 and the soft metal bump B6 is performed with the hard metal bump A5 and the soft metal bump B6 facing each other. As a result, the bump A5 is shaped into a projection while the bump B6 is shaped into a depression (see the cross-section shown in (c) of FIG. 2G). A difference from FIG. 2A is that the components are the semiconductor element A1 and the lead frame 10. The configuration, in which the lead frame itself plays a role as an external terminal, eliminates the need for (i) a through-hole that needs to be bored through the substrate for the external terminal to be attached to the substrate and (ii) the external terminal, thus reducing the number of steps.

Note that the relationship between the hard metal bump A5 at the upper portion and the soft metal bump B6 at the lower portion is not limited to that as described in the embodiments.

As for the metal composition of a bump, it is desirable that the bump be made of gold, silver, or copper. These metals are well known to have good press bonding compatibility with each other, are readily available as common materials, and have many instances of actually use. Furthermore, a desirable configuration in which these metals are used is one in which one bump is made of copper. This is because copper is low in material cost and is the highest in hardness of the three metals. For bonding in a semiconductor device, it is desirable that the other bump be made of gold. This is because gold has many instances of actual use and is the softest of the three metals. In a case where the cost is required to be lower than that of gold or in a case where a oxidization prevention environment, for example, which is required when copper is used is not provided, the selection of silver, which is harder than gold and softer than copper, makes it possible to bond bump configurations differing in hardness.

When a copper bump is formed by using a wire bonding device and a bump bonding device, the copper bump is formed in an inert atmosphere from a copper wire coated with a metal such as palladium. This method makes it possible to prevent the oxidization of the surface of the bump, to simplify process management and material management, and to increase bonding reliability. Furthermore, bonding reliability can be increased by plasma processing, for example, and by washing and activating the surface of the bump.

Modifications of a mounting structure of a semiconductor device are described below.

[Modification 1 of Embodiment of Mounting Structure of Semiconductor Device]

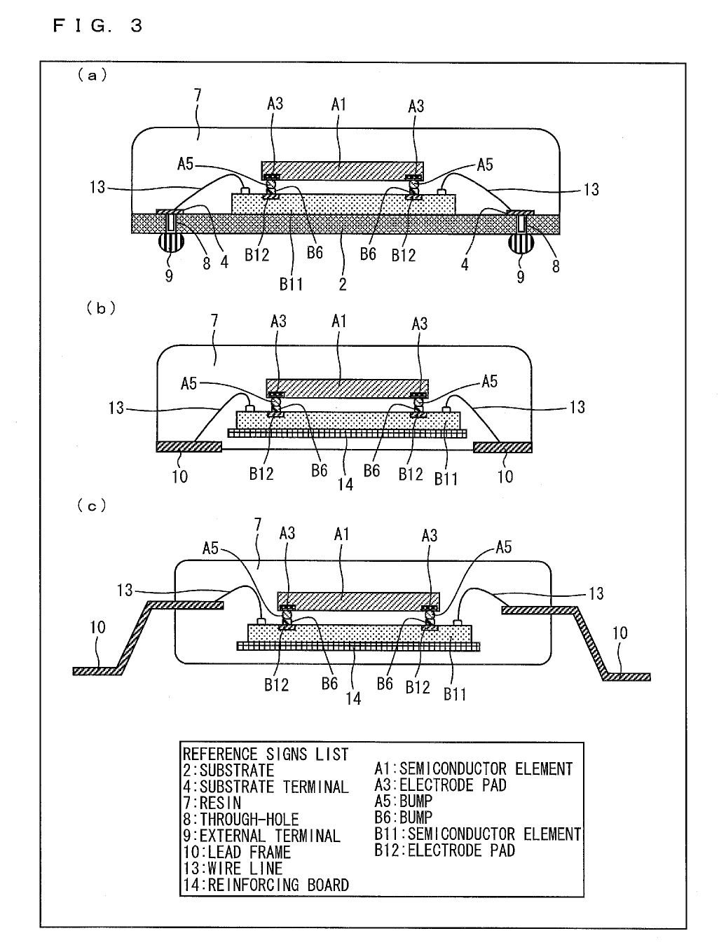

A modification of an embodiment of a mounting structure of a semiconductor device according to the present invention is described below with reference to (a) of FIG. 3.

(a) of FIG. 3 is a cross-sectional view of a modification of a mounting structure of a semiconductor device according to the present invention.

As shown in (a) of FIG. 3, the semiconductor device includes three components (a semiconductor element A1, a semiconductor element B11, and a substrate 2). Each of the components has at least one connection terminal (an electrode pad A3, an electrode pad B12, and a substrate terminal 4) on a surface thereof. The semiconductor element A1 and the semiconductor element B11 are electrically bonded to each other via a plurality of connection terminals (electrode pads A3 and electrode pads B12) of each of the components. The electrical bonding is made with a bump A5 and a bump B6 that are made of different metals differing in hardness. Furthermore, the substrate 2 and the semiconductor element B11 are electrically bonded to each other. This electrical bonding is made with wire lines 13. A resin 7 is provided so as to cover a front surface of the substrate 2. An external terminal 9 is provided on a rear surface of the substrate 2 so as to be electrically connected to the semiconductor element B11 via the wire lines 13, the substrate terminal 4, and the through-hole 8.

A difference from (a) of FIG. 1 is that the semiconductor device shown in (a) of FIG. 3 has three components. The electrical bonding of the three components, namely the semiconductor element A1, the semiconductor element B11, and the substrate 2, with use of the bonding of the wire lines makes it possible to be compatible with a more complicated circuit and to reduce the circuit area.

[Modification 2 of Embodiment of Mounting Structure of Semiconductor Device]

A modification of an embodiment of a mounting structure of a semiconductor device according to the present invention is described below with reference to (b) of FIG. 3.

(b) of FIG. 3 is a cross-sectional view of a modification of a mounting structure of a semiconductor device according to the present invention.

As shown in (b) of FIG. 3, the semiconductor device includes three components (a semiconductor element A1, a semiconductor element B11, and a lead frame 10). Each of the components has at least one connection terminal (an electrode pad A3, an electrode pad B12, and a lead frame 10) on a surface thereof. The semiconductor element A1 and the semiconductor element B11 which is fixed to a reinforcing board 14, are electrically bonded to each other via a plurality of connection terminals (electrode pads A3 and electrode pads B12) of each of the components. The electrical bonding is made by using bumps A5 and bumps B6 that are made of different metals differing in hardness. Furthermore, the semiconductor element B11, which is fixed to the reinforcing board 14, and the lead frames 10 are electrically bonded to each other. This electrical bonding is made with wire lines 13. A resin 7 is provided so as to cover a front surface of the substrate 2.

A difference of (b) of FIG. 3 from (a) of FIG. 3 is found in components. The lead frame 10 is used instead of the substrate 2 shown in (a) of FIG. 3. Although the reinforcing board 14 is needed, the lead frame 10 itself plays a role as an external terminal. This eliminates the need for (i) a through-hole and (ii) an external terminal that need to be bored through the substrate for the external terminal to be attached to the substrate. This leads to a reduction in the number of steps decreases, and by extension to a reduction in cost.

[Modification 3 of Embodiment of Mounting Structure of Semiconductor Device]

A modification of an embodiment of a mounting structure of a semiconductor device according to the present invention is described below with reference to (c) of FIG. 3.

(c) of FIG. 3 is a cross-sectional view of a modification of a mounting structure of a semiconductor device according to the present invention.

A difference of (c) of FIG. 3 from (b) of FIG. 3 is found in the shape of the lead frame of Modification 2 of Embodiment. Since the lead frame can take any shape, the lead frame can be disposed at any location where it is needed.

[Manufacturing Method]

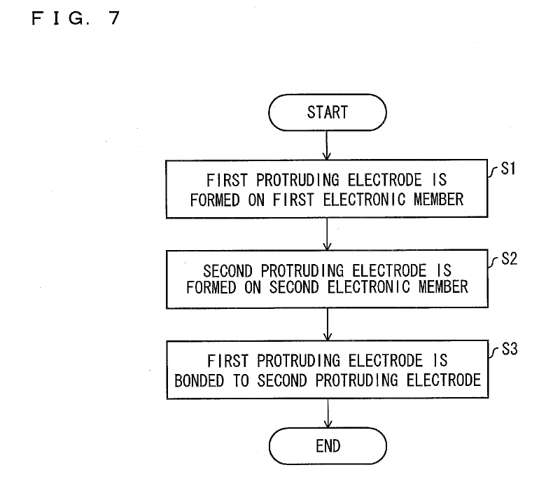

Next, a method for manufacturing a semiconductor device is described below with reference to FIG. 7. FIG. 7 is a flow chart showing steps of the method.

As shown in FIG. 7, a semiconductor device is manufactured through the following steps. First, a first protruding electrode is formed on a first electronic member (Step S1). In this step, the first protruding electrode is formed by using a wire bonding device and a bump bonding device.

Next, a second protruding electrode is formed on a second electronic member (Step S2). In this step, the second protruding electrode is formed by using a wire bonding device and a bump bonding device or by using a plating method and an evaporation method.

Next, the first protruding electrode is embedded in (bonded to) the second protruding electrode (Step S3). In this step, the first protruding electrode is pressed and bonded to the second protruding electrode through the application of a load. Furthermore, metal bonding based on thermal pressure bonding is possible through the application of heat.

Moreover, the first electronic component refers to a substrate or to a semiconductor element mounted on a substrate. The second electronic component refers to a semiconductor element. Furthermore, it is desirable that the first protruding electrode be made of copper and the second protruding electrode be made of gold.

The present invention is not limited to the description of the embodiments above, but may be altered by a skilled person within the scope of the claims. An embodiment based on a proper combination of technical means disclosed in different embodiments is encompassed in the technical scope of the present invention.

In addition, examples of bonding between connection terminals by conventional technique are described below for reference.

### Example 1 of Bonding between Connection Terminals by Conventional Technique

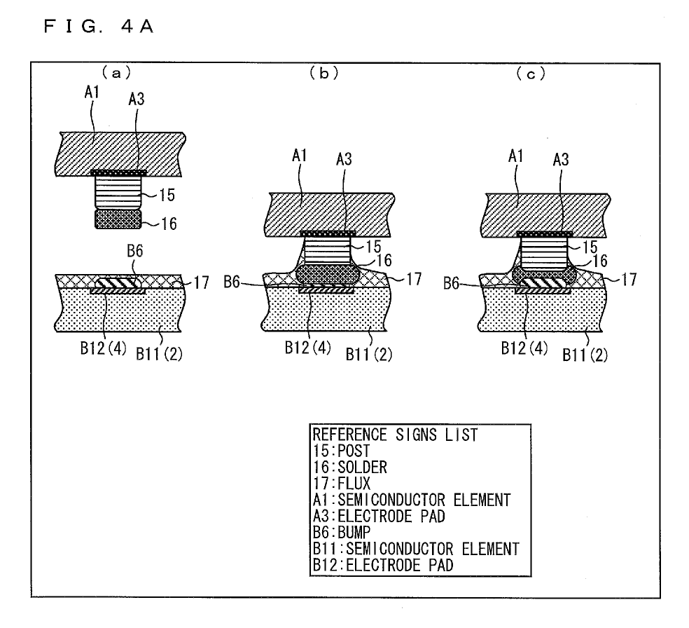

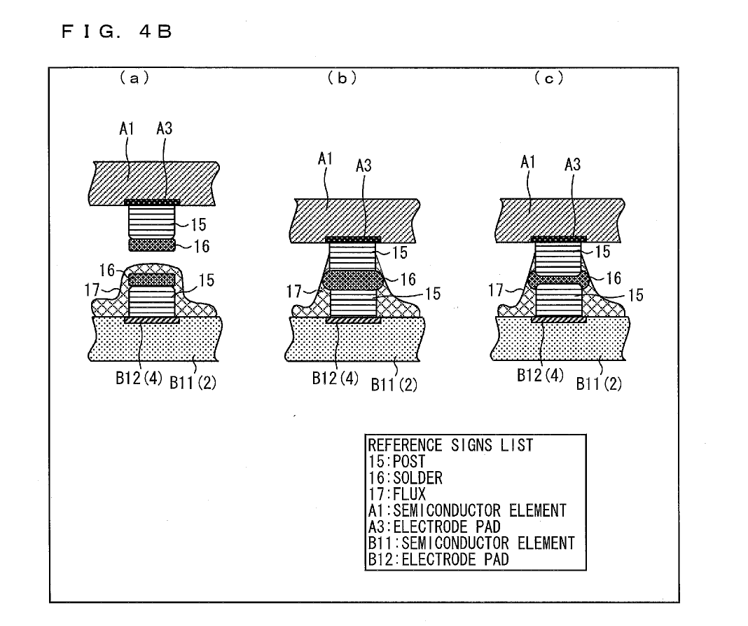

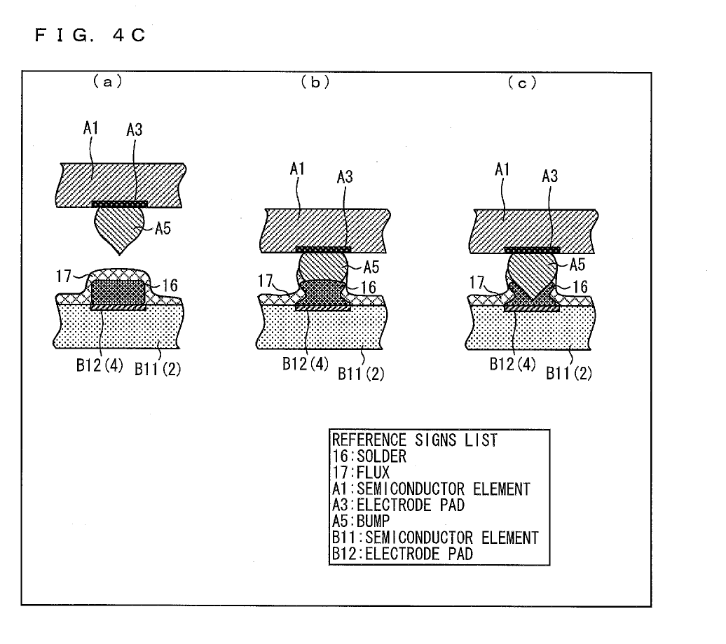

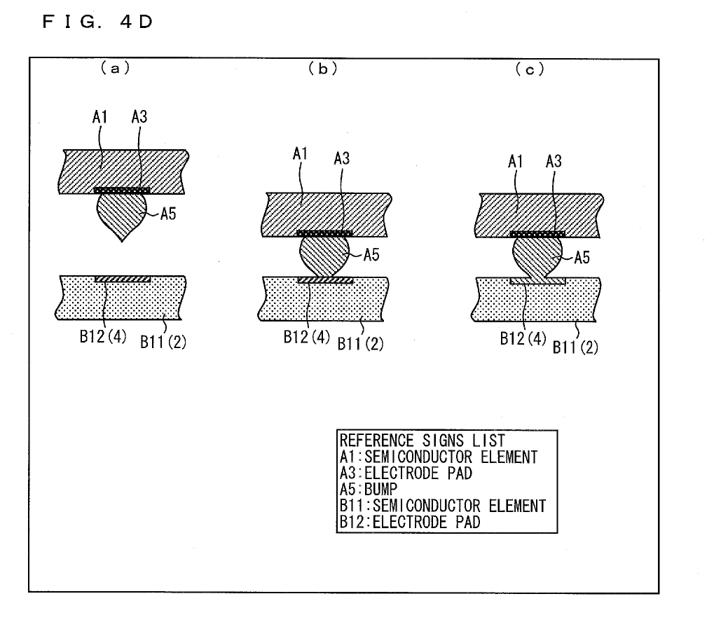

Bonding between connection terminals by a conventional technique is described with reference to FIG. 4A.

FIG. 4A is a cross-sectional view of bonding between connection terminals by a conventional technique.

FIG. 4A is an example of bonding between a semiconductor element A1 and a semiconductor element B11 (or a substrate 2). A post 15 is formed on the electrode pad A3 of the semiconductor element A1. Solder 16 is applied to the end of the post 15. A metal layer or a bump B6 is formed on an electrode pad B12 (or a substrate terminal 4) of the semiconductor element B11 (or the substrate 2) by a plating method and an evaporation method, and then flux 17 is applied not only to the surface of the metal layer or the surface of the bump B6 but also to the surface of the semiconductor element B11 (or the substrate 2). Flip chip mounting is performed with the solder 16 and the flux 17 facing each other, the solder 16 is melted by reflowing, and then (i) the post 15 and (ii) the metal layer or the bump B6 are bonded to each other by solder melting. As a result, the solder 16 is sandwiched between (i) the post 15 and (ii) the metal layer or the bump B6 (see the cross-section shown in (c) of FIG. 4A).

### Example 2 of Bonding Between Connection Terminals by Conventional Technique

Bonding between connection terminals by a conventional technique is described below with reference to FIG. 4B.

FIG. 4B is a cross-sectional view of bonding between connection terminals by a conventional technique.

FIG. 4B is an example of bonding between a semiconductor element A1 and a semiconductor element B11 (or a substrate 2). A post 15 is formed on an electrode pad A3 of the semiconductor element A1, and another post 15 is formed on an electrode pad B12 (or a substrate terminal 4) of the semiconductor element B11 (or the substrate 2). Solder 16 is applied to the respective ends of the posts 15. Flux 17 is applied to the surface of the semiconductor element B11 (or the substrate 2). Flip chip mounting is performed with the posts 15 facing each other, and then the solder 16 is melted by reflowing, and the posts 15 are bonded to each other by solder melting. As a result, the posts 15 face each other with the solder 16 sandwiched therebetween (see the cross-section shown in (c) of FIG. 4A).

### Example 3 of Bonding between Connection Terminals by Conventional Technique

Bonding between connection terminals by a conventional technique is described below with reference to FIG. 4C.

FIG. 4C is a cross-sectional view of bonding between connection terminals by a conventional technique.

FIG. 4C is an example of bonding between a semiconductor element A1 and a semiconductor element B11 (or a substrate 2). A bump A5 is formed on an electrode pad A3 of the semiconductor element A1 by using a wire bonding device and a bump bonding device. Solder (solder bump) 16 is formed on an electrode pad B12 (or a substrate terminal 4) of the semiconductor element B11 (or the substrate 2). Flux 17 is applied to the surface of the semiconductor element B11 (or the substrate 2). Flip chip mounting is performed with the bump A5 and the solder (the solder bump) 16 facing each other. After the solder (the solder bump) 16 is melted by reflowing, the bump A5 and the electrode pad B12 (or the substrate 2) are bonded by solder melting. As a result, the bump A5 is shaped into a projection while the solder (solder bump) 16 is shaped into a depression (see the cross-section shown in (c) of FIG. 4C).

A difference of Examples 1, 2, and 3 of bonding between connection terminals by the conventional techniques from the bonding between connection terminals according to the present invention is that solder is used for bonding. When solder is used for bonding, a large number of processes and materials, such as the application of solder to the bump and the post, the application of flux, reflow, and the removal of flux, are required. This means long time and high cost. Moreover, electrical conduction is impossible due to (i) a short circuit with an adjacent terminal by a fine-pitch solder bridge or (ii) the remelting of a solder joint by heat of reflow, for example, which is applied through the assembly by a user.

### Example 4 of Bonding between Connection Terminals by Conventional Technique

Bonding between connection terminals by a conventional technique is described below with reference to FIG. 4D.

FIG. 4D is a cross-sectional view of bonding between connection terminals by a conventional technique.

FIG. 4D is an example of bonding between a semiconductor element A1 and a semiconductor element B11 (or the substrate 2). A bump A5 is formed on an electrode pad A3 of the semiconductor element A1 by using a wire bonding device and a bump bonding device. Flip chip mounting is performed with the bump A5 and an electrode pad B12 (or a substrate terminal 4) facing each other above the electrode pad B12 (or the substrate terminal 4) of the semiconductor element B11 (or the substrate 2), and then the bump A5 and the electrode pad B12 (or the substrate terminal 4) are metallically bonded by ultrasonic thermal pressure bonding. As a result, the bump A5 and the electrode pad B12 (or the substrate terminal 4) are fused with each other (see the cross-section shown in (c) of FIG. 4D).

A main difference from the present invention is that ultrasonic waves are used for bonding. When ultrasonic waves are used for bonding, damage can occur, such as the deformation of the bump and detachment of the bump due to the amplitude of the ultrasonic waves.

In order to solve the problems mentioned above, a semiconductor device according to the present invention includes: a first electronic component having a first protruding electrode; and a second electronic component having a second protruding electrode, the second protruding electrode being connected to the first protruding electrode, the first protruding electrode and the second protruding electrode being made of different metal materials, the first protruding electrode being harder than the second protruding electrode, the first protruding electrode having an end facing the second protruding electrode and embedded in the second protruding electrode.

According to the configuration, since the first protruding electrode and the second protruding electrode are made of different metal materials instead of being made of the same type of metal and the metal materials differ in hardness, the first protruding electrode is embedded in the second protruding electrode, and the interface between the bonded surface of the first protruding electrode and the bonded surface of the second protruding electrode as viewed in cross section are shaped into a projection and a depression, respectively. A relationship between the projection and the depression causes friction to be created due to a slide at the interface between the different protruding electrodes and makes it easier to for newly-formed surfaces to be exposed. This enables bonding without using ultrasonic waves that have been used to expose newly-formed surfaces. Therefore, the problem with ultrasonic bonding can be avoided. Specifically, damage such as deformation or detachment of a bump due to the amplitude of ultrasonic waves can be avoided, while such damage might be done in the case of ultrasonic bonding.

Furthermore, the semiconductor device according to the present invention is preferably configured such that the first protruding electrode and the second protruding electrode are directly bonded to each other.

According to the configuration, since the first protruding electrode and the second protruding electrode are directly connected to each other without solder, the problem with solder bonding can be avoided. Specifically, a large number of processes and materials, cost, and time that are necessary for solder bonding, such as the application of solder, the application of flux, reflow, and the removal of flux, can be reduced. Moreover, a failure of electrical conduction due to (i) a short circuit with an adjacent terminal by a fine-pitch solder bridge or (ii) the remelting of a solder joint by heat of reflow, for example, which is applied through the assembly by a user can be avoided, too.

Furthermore, the semiconductor device according to the present invention is preferably configured such that the end of the first protruding electrode is a pointed end.

According to the configuration, since the end of the first protruding electrode is a pointed end, the first protruding electrode is more easily embedded in the second protruding electrode than the first protruding electrode would be if the first protruding electrode had a rounded end, and can therefore be more firmly bonded to the second protruding electrode.

Furthermore, the semiconductor device according to the present invention is preferably configured such that the first protruding electrode is a stud bump.

According to the configuration, since the first protruding electrode is a stud bump, a bump having a sharp shape can be formed, is easily embedded in the second protruding electrode, and can be more firmly bonded to the second protruding electrode. Furthermore, a bump can be directly formed on the electrode pad of each individual semiconductor element. This means that the positions where these bumps are formed can be determined and changed in accordance with position information only. This makes it possible to form the bumps only on non-defective ones of the semiconductor elements fabricated on a wafer, thus making it possible to avoid the increase in cost due to the formation of defective semiconductor elements. Further, since the bumps can be formed on the same manufacturing line as that on which flip chip bonding is performed, the transport damage can be avoided. In a case where the first protruding electrode is made of copper, the bump formation is performed in an inert atmosphere from a copper wire coated with a metal such as palladium. This reduces the oxidization of copper, simplifies process management and material management, enables flip chip bonding in a more fresh state, and increases bonding reliability.

Furthermore, the semiconductor device according to the present invention is configured such that the second protruding electrode is a stud bump or a plated bump.

According to the configuration, in a case where the second protruding electrode is a plated bump, a batch of bumps can be formed on a wafer-by-wafer basis. This means that the bumps can be formed in the shortest amount of time and the overall time is therefore reduced. The bumps can be easily formed in a planar shape. Therefore, since the soft metal bump comes to have a wider planar surface when the end of the hard metal bump is pressed onto the soft metal bump, a relationship between a projection and a depression as viewed in cross section can be easily established even in a case where a shift in position occurs during flip chip bonding. This ensures a reliable bonding state.

Furthermore, the semiconductor device according to the present invention is preferable configured such that in a direction in which the end of the first protruding electrode is embedded in the second protruding electrode, a length of the second protruding electrode is greater than a length of the end of the first protruding electrode.

According to the configuration, the step of forming a bump located opposite to the first protruding electrode can be eliminated by direct bonding between the first protruding electrode and the second protruding electrode located opposite to the first protruding electrode. This makes it possible to speed up the process, and by extension to achieve a cost reduction.

Furthermore, the semiconductor device according to the present invention is preferably configured such that: the first electronic component is a substrate or a semiconductor element mounted on a substrate; the first protruding electrode is a copper bump; the second electronic component is a semiconductor element; and the second protruding electrode is a gold bump.

According to the configuration, copper and gold have good press bonding compatibility with each other, are readily available as common materials, have many instances of actual use, and highly reliable in use for bonding. A desirable configuration is one in which the harder metal bump is made of copper while the softer metal bump is made of gold. This makes it possible to form metal bumps that are highly reliable in bonding of the semiconductor device and low in material cost. Moreover, in the application of heat during bonding, heat is applied not to the substrate but to the semiconductor element, as the application of heat to the substrate can generate gases or reactants when the substrate is made of resin. The formation of copper bumps on the substrate, to which heat is not applied, can prevent the oxidization of copper.

Furthermore, the semiconductor device according to the present invention is preferably configured such that the first protruding electrode is partially covered with a metal material that is different from a metal material of which the first protruding electrode is made.

According to the configuration, the copper bump serving as the first protruding electrode is formed in an inert atmosphere from a copper wire coated with a different metal (metal that is not easily oxidized) (e.g., palladium). This reduces the oxidization of the surface of the bump, simplifies process management and material management, and increases bonding reliability.

Furthermore, the semiconductor device according to the present invention is preferably configured such that the second protruding electrode has a structure in which two types of metal materials are stacked.

According to the configuration, in the case of a problem such as a failure to fill a space between with components a fixing material or a sealing material, bonding the first electronic component and the second electronic component to each other by using three bumps makes it possible, for example, to secure a clearance between one component and another, to increase a level of filling, and to adjust the clearance.

A method for manufacturing a semiconductor device according to the present invention is a method for manufacturing the semiconductor device, including the steps of: (a) forming the first protruding electrode on the first electronic component from copper by using a wire bonding device; (b) forming the second protruding electrode on the second electronic component from gold by using a wire bonding device or a plating method; and (c) embedding the end of the first protruding electrode in the second protruding electrode while applying heat to the second electronic component.

The method makes it possible to manufacture a semiconductor device in which the first protruding electrode formed on the first electronic component and the second protruding electrode formed on the second electronic component are directly bonded to each other without using solder, ultrasonic waves, or the like.

Furthermore, in the manufacturing method according to the present invention, it is preferable that at least one of the first electronic component and the second electronic component be a semiconductor element, and that formation of the first or second protruding electrode on the semiconductor element be performed on each individual semiconductor chip into which a wafer has been divided.

According to the manufacturing method, the positions where the bumps are formed can be individually adjusted with respect to the electrode pads, the substrate terminals, and the like. Therefore, the bumps can be formed with high levels of positional accuracy. Furthermore, the formation of bumps on a wafer presents the following problems. In the case of formation of bumps on a wafer before grinding, damage is done to the bumps when a surface protecting sheet is removed during or after grinding. In the case of formation of bumps on a wafer after grinding, since a sheet for protecting a thin wafer is in a space between the chip and the stage, constraints are imposed on bump formation. Moreover, in both the case of formation of bumps on a wafer before grinding and the case of formation of bumps on a wafer after grinding, constraints are imposed when a semiconductor element is mounted on a substrate or reinforcing board of a semiconductor device constituted by three components. Therefore, the problems can be avoided by performing bump formation on each individual semiconductor chip into which a wafer has been divided, instead of performing bump formation on a wafer, as in the case of the method described above.

Furthermore, in the method for manufacturing a semiconductor device according to the present invention, it is preferable that step (a) be performed in an environment filled with an inert gas.

According to the manufacturing method, the formation of the bump in an inert atmosphere prevent the oxidization of the surface of the bump and simplifies simplify process management and material management, thus making it possible to manufacture a semiconductor device that is high in bonding reliability.

Furthermore, it is preferable that the method further include, as a step preceding step (c), the step of washing a surface of the first protruding electrode and a surface of the second protruding electrode.

According to the manufacturing method, the surface of the first protruding electrode and the surface of the second protruding electrode are washed and activated by washing, for example, with plasma processing. This makes it possible to manufacture a semiconductor device that is high in bonding reliability.

### INDUSTRIAL APPLICABILITY

The present invention is applicable to a semiconductor device manufactured by using a flip chip technique and a method for manufacturing a semiconductor device by using the flip chip technique.

### REFERENCE SIGNS LIST

A1 Semiconductor element
2 Substrate
A3 Electrode pad
4 Substrate terminal
A5 Bump
B6 Bump
7 Resin
8 Through-hole
9 External terminal
10 Lead frame
B11 Semiconductor element
B12 Electrode pad
13 Wire line
14 Reinforcing board
15 Post
16 Solder
17 Flux
31 Wire
32a Electrode pad
33 Ball portion
34 Capillary
35 Bump
41 Resist opening
42 Resist (photosensitive polymer film)
43 Barrier metal layer
44 Protecting film
45 Pad
46 Bump (before reflow)
46a Bump (after reflow)

1. A semiconductor device comprising:
a first electronic component having a first protruding electrode; and
a second electronic component having a second protruding electrode, the second protruding electrode being connected to the first protruding electrode,
the first protruding electrode and the second protruding electrode are connected to each other without using ultrasonic waves,
the first protruding electrode and the second protruding electrode being made of different metal materials,
the first protruding electrode being harder than the second protruding electrode,
the first protruding electrode having an end facing the second protruding electrode and embedded in the second protruding electrode.

2. The semiconductor device as set forth in claim 1, wherein the first protruding electrode and the second protruding electrode are directly bonded to each other.

3. The semiconductor device as set forth in claim 1, wherein the end of the first protruding electrode is a pointed end.

4. The semiconductor device as set forth in claim 1, wherein the first protruding electrode is a stud bump.

5. The semiconductor device as set forth in claim 1, wherein the second protruding electrode is a stud bump or a plated bump.

6. The semiconductor device as set forth in claim 1, wherein in a direction in which the end of the first protruding electrode is embedded in the second protruding electrode, a length of the second protruding electrode is greater than a length of the end of the first protruding electrode.

7. The semiconductor device as set forth in claim 1, wherein:
the first electronic component is a substrate or a semiconductor element mounted on a substrate;
the first protruding electrode is a copper bump;
the second electronic component is a semiconductor element; and
the second protruding electrode is a gold bump.

8. The semiconductor device as set forth in claim 7, wherein the first protruding electrode is partially covered with a metal material that is different from a metal material of which the first protruding electrode is made.

9. The semiconductor device as set forth in claim 1, wherein the second protruding electrode has a structure in which two types of metal materials are stacked.

10. A method for manufacturing a semiconductor device, the semiconductor device including:
a first electronic component having a first protruding electrode; and
a second electronic component having a second protruding electrode, the second protruding electrode bring connected to the first protruding electrode,
the first protruding electrode and the second protruding electrode are connected to each other without using ultrasonic waves,
the first protruding electrode and the second protruding electrode being made of different metal materials,
the first protruding electrode being harder than the second protruding electrode,
the first protruding electrode having an end facing the second protruding electrode and embedded in the second protruding electrode
the method
comprising the steps of:
(a) forming the first protruding electrode on the first electronic component from copper by using a wire bonding device;
(b) forming the second protruding electrode on the second electronic component from gold by using a wire bonding device or a plating method; and
(c) embedding the end of the first protruding electrode in the second protruding electrode while applying heat to the second electronic component.

11. The method as set forth in claim 10, wherein:
at least one of the first electronic component and the second electronic component is a semiconductor element; and
formation of the first or second protruding electrode on the semiconductor element is performed on each individual semiconductor chip into which a wafer has been divided.

12. The method as set forth in claim 10, wherein step (a) is performed in an environment filled with an inert gas.

13. The method of manufacturing a semiconductor device as set forth in claim 10, further comprising, as a step preceding step (c), the step of washing a surface of the first protruding electrode and a surface of the second protruding electrode.
